(19) United States
(12) Patent Application Publication
(10) Pub. No.: US 2020/0132369 A1
(43) Pub. Date: Apr. 30, 2020

(54) CASSETTE DRYING APPARATUS, MANUFACTURING APPARATUS FOR EL DEVICE, AND MANUFACTURING METHOD FOR EL DEVICE

(71) Applicant: Sharp Kabushiki Kaisha, Sakai City, Osaka (JP)

(72) Inventor: Shigeru KAWAGISHI, Sakai City (JP)

(21) Appl. No.: 16/465,250

(22) PCT Filed: Jul. 18, 2017
(86) PCT No.: PCT/JP2017/025948

§ 371 Date: May 30, 2019

(51) Int. Cl. F26B 3/04; H01L 21/67; F26B 21/00; F26B 25/06

(52) U.S. Cl. CPC F26B 3/04; H01L 21/67034; H01L 33/005; F26B 25/06; F26B 21/004

(57) ABSTRACT

A cassette drying apparatus includes first to fourth blowing nozzles configured to respectively inject hot air along first to fourth side face portions of a substrate cassette, and an exhaust duct disposed in a central portion of a bottom face of the substrate cassette. The first to fourth blowing nozzles are each disposed in a direction to inject the hot air in a clockwise direction around the exhaust duct.

### TECHNICAL FIELD

The disclosure relates to a cassette drying apparatus configured to inject hot air onto a substrate accommodated in a cassette formed by assembling columnar members in a rectangular parallelepiped shape to dry the substrate, a cassette dryness method, a manufacturing apparatus for an electro luminescence (EL) device, and manufacturing method for an EL device.

### BACKGROUND ART

Heretofore, there is known a substrate-drying apparatus configured to inject hot air onto a substrate accommodated in a cassette formed by assembling columnar members in a rectangular parallelepiped shape to dry the substrate (PTL 1). The substrate-drying apparatus includes a substrate cassette accommodated in a drying chamber. The substrate cassette has a frame body formed by assembling main columns in a rectangular parallelepiped shape. On the right and left of the frame body, a plurality of pairs of wire-fixing members extending vertically are provided back and forth, and side by side. Wires to be provided up and down at a predetermined interval are coupled to the pairs of wire-fixing members. On the wires disposed in front and behind at the same height, a mother glass substrate is inserted.

The drying chamber is provided, on the inner face, with a plurality of blowing nozzles that are disposed side by side to be able to inject hot air toward the mother glass substrate.

### CITATION LIST

### Patent Literature

PTL 1: JP 2011-153732 A (published Aug. 11, 2011)

### SUMMARY

### Technical Problem

In a manufacturing process of an EL device such as an organic light emitting diode, an inorganic light emitting diode, a quantum dot light emitting diode, mother glass substrates for forming an EL device are cleaned, and then in a drying step for drying the mother glass substrates, hot air is applied to a substrate cassette accommodating the mother glass substrates to dry the mother glass substrates.

Unfortunately, a fine adjustment of the blowing nozzles is required that allow hot air to be uniformly applied to the mother glass substrates to prevent incomplete drying of the mother glass substrates from occurring. Such an adjustment operation is complicated.

### Solution to Problem

A cassette drying apparatus according to an aspect of the disclosure includes a cassette formed by assembling columnar members in a polygonal pillar shape, the cassette being configured to accommodate a substrate, a plurality of blowing nozzles configured to inject air for drying the substrate accommodated in the cassette, and an exhaust duct disposed at a position corresponding to a central portion of a top face or a bottom face of the cassette. The plurality of blowing nozzles are disposed in a direction to inject the air in a clockwise direction around the exhaust duct, or the plurality of blowing nozzles are disposed in a direction to inject the air in a counterclockwise direction around the exhaust duct.

### Advantageous Effects of Disclosure

The aspect of the disclosure eliminates the need for a complicated adjustment of blowing nozzles to apply hot air to the mother glass substrates uniformly to prevent incomplete drying of the mother glass substrates from occurring.

### BRIEF DESCRIPTION OF DRAWINGS

FIG. 1 is a perspective view of a cassette drying apparatus according to a first embodiment.

FIG. 2 is a plan view of a bottom face of the cassette drying apparatus.

FIG. 3 is a plan view of the bottom face illustrating a placement direction of each of the blowing nozzles provided in the cassette drying apparatus.

FIG. 4A is a schematic perspective view illustrating a substrate cleaning apparatus according to a comparative example, and FIG. 4B is a schematic perspective view illustrating a cassette drying apparatus according to the comparative example.

FIG. 5 is a plan view of a bottom face of the cassette drying apparatus according to the comparative example.

FIG. 6A is a front view of a cassette provided in a cassette drying apparatus according to a second embodiment, FIG. 6B is a plan view of the cassette, FIG. 6C is a side view of the cassette, and FIG. 6D is a detailed view of a side plate provided in the cassette.

FIG. 7 is a plan view of a bottom face illustrating a placement direction of each of the blowing nozzles provided in the cassette drying apparatus.

FIG. 8A illustrates an example of an injection direction of hot air from one of the blowing nozzles, and FIG. 8B illustrates another example of an injection direction of hot air from one of the blowing nozzles.

FIG. 9A is a schematic perspective view illustrating the cassette drying apparatus, and FIG. 9B is a schematic perspective view illustrating a cassette drying apparatus according to a comparative example.

FIG. 10 is a plan view of a bottom face illustrating a placement direction of each of blowing nozzles provided in a cassette drying apparatus according to a third embodiment.

### DESCRIPTION OF EMBODIMENTS

### First Embodiment

### Configuration of Cassette Drying Apparatus 1

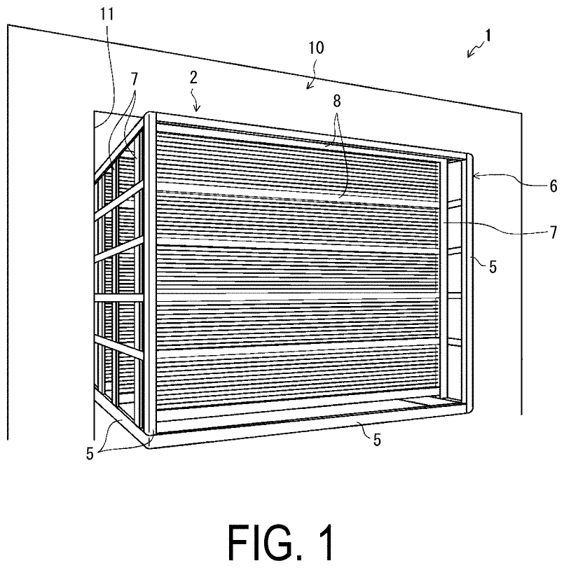

FIG. 1 is a perspective view of a cassette drying apparatus 1 according to an embodiment. The cassette drying apparatus 1 includes a substrate cassette 2 accommodated in a drying chamber 10. The substrate cassette 2 has a frame body 6 formed by assembling columnar members 5 in a rectangular parallelepiped shape. On the right and left of the frame body 6, a plurality of pairs of wire-fixing members 7 extending vertically are provided in front and behind, and side by side. Wires 8 to be provided up and down at a predetermined interval are coupled to the pairs of right and left wire-fixing members 7. On the wires 8 disposed in front and behind at the same height, a mother glass substrate (substrate) for forming an EL device is inserted. The EL device includes an organic light emitting diode, an inorganic light emitting diode, or a quantum dot light emitting diode.

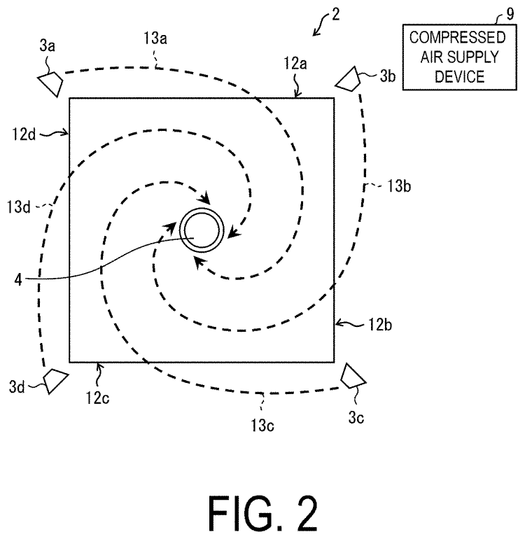

FIG. 2 is a plan view of the cassette drying apparatus 1. The substrate cassette 2 includes a first side face portion 12a, a second side face portion 12b, a third side face portion 12c, and a fourth side face portion 12d. The cassette drying apparatus 1 includes a first blowing nozzle 3a configured to inject hot air 13a (air) toward the second side face portion 12b from the first side face portion 12a on a fourth side face portion 12d side, a second blowing nozzle 3b configured to inject hot air 13b toward the third side face portion 12c from the second side face portion 12b on a first side face portion 12a side, a third blowing nozzle 3c configured to inject hot air 13c toward the fourth side face portion 12d from the third side face portion 12c on a second side face portion 12b side, and a fourth blowing nozzle 3d configured to inject hot air 13d toward the first side face portion 12a from the fourth side face portion 12d on a third side face portion 12c side.

At a position corresponding to a central portion of a bottom face of the substrate cassette 2, an exhaust duct 4 for exhausting the hot air 13a to 13d respectively injected from the first to fourth blowing nozzles 3a to 3d is disposed. The exhaust duct 4 may be disposed at a position corresponding to a central portion of a top face of the substrate cassette 2.

The cassette drying apparatus 1 includes a compressed air supply device 9 that supplies compressed air to the first to fourth blowing nozzles 3a to 3d.

While an example of the frame body 6 formed by assembling the columnar members 5 in a rectangular parallelepiped shape is described, the disclosure is not limited to this example. The columnar members 5 need to be assembled in a polygonal pillar shape, and thus the columnar members 5 may be assembled in a triangular pillar shape, for example. In addition, while an example of the exhaust duct 4 disposed at the position corresponding to the central portion of the top face of the substrate cassette 2 is described, the disclosure is not limited to this example, and thus the exhaust duct 4 may be disposed at the central portion of the bottom face thereof, for example.

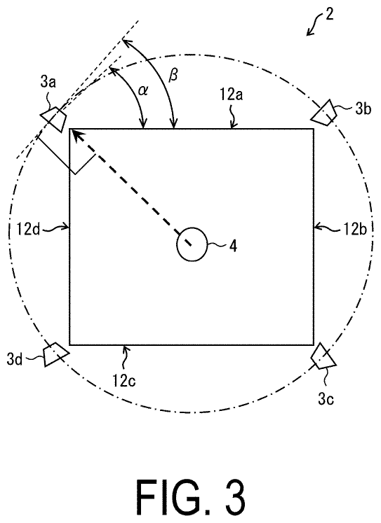

FIG. 3 is a plan view of the bottom face illustrating a placement direction of each of the first to fourth blowing nozzles 3a to 3d provided in the cassette drying apparatus 1. The exhaust duct 4 is disposed in the central portion of the bottom face of the cassette 2. The first to fourth blowing nozzles 3a to 3d are respectively disposed on the extension lines of four line segments connecting the exhaust duct 4 to vertexes of the cassette 2. An angle α between a direction of hot air injected from the first blowing nozzle 3a and the first side face portion 12a of the cassette 2 is equal to or less than an angle β between a tangential line of a circle and the first side face portion 12a of the cassette 2, the circle being centered on the exhaust duct 4 and passing through the blowing nozzles 3a to 3d. It is preferable that in a case of indicating an outward angle as a positive angle as illustrated in FIG. 3, the angle α is from −20 degrees to +45 degrees. The second to fourth blowing nozzles 3b to 3d are also configured like the first blowing nozzle 3a.

As described above, the first to fourth blowing nozzles 3a to 3d are each disposed in a different direction to respectively inject the hot air 13a to 13d in a clockwise direction around the exhaust duct 4. Conversely, the first to fourth blowing nozzle 3a to 3d may be each disposed in a different direction to respectively inject the hot air 13a to 13d in a counterclockwise direction around the exhaust duct 4.

### Operation of Cassette Drying Apparatus 1

The cassette drying apparatus 1 configured as described above operates as follows.

First, a mother glass substrate is accommodated in the substrate cassette 2. Then, the substrate cassette 2 accommodating the mother glass substrate is carried into the drying chamber 10 through a carry-in port 11. Next, the first blowing nozzle 3a is disposed in the first side face portion 12a of the substrate cassette 2 carried into the drying chamber 10, and the second blowing nozzle 3b is disposed in the second side face portion 12b. Then, the third blowing nozzle 3c is disposed in the third side face portion 12c, and the fourth blowing nozzle 3d is disposed in the fourth side face portion 12d.

After that, the compressed air supply device 9 supplies compressed air to the first to fourth blowing nozzles 3a to 3d. Then, the first blowing nozzle 3a injects the hot air 13a toward the second side face portion 12b from the first side face portion 12a on the fourth side face portion 12d side. The second blowing nozzle 3b injects the hot air 13b toward the third side face portion 12c from the second side face portion 12b on the first side face portion 12a side. The third blowing nozzle 3c injects the hot air 13c toward the fourth side face portion 12d from the third side face portion 12c on the second side face portion 12b side. The fourth blowing nozzle 3d injects the hot air 13d toward the first side face portion 12a from the fourth side face portion 12d on the third side face portion 12c side.

The hot air 13a injected from the first blowing nozzle 3a, the hot air 13b injected from the second blowing nozzle 3b, the hot air 13c injected from the third blowing nozzle 3c, and the hot air 13d injected from the fourth blowing nozzle 3d, are exhausted from the exhaust duct 4 while swirling in the substrate cassette 2.

This causes the hot air 13a to 13d to flow in the substrate cassette 2 in a spiral manner so that the hot air uniformly strikes a plurality of mother glass substrates accommodated in the substrate cassette 2. Thus, the mother glass substrates can be uniformly dried.

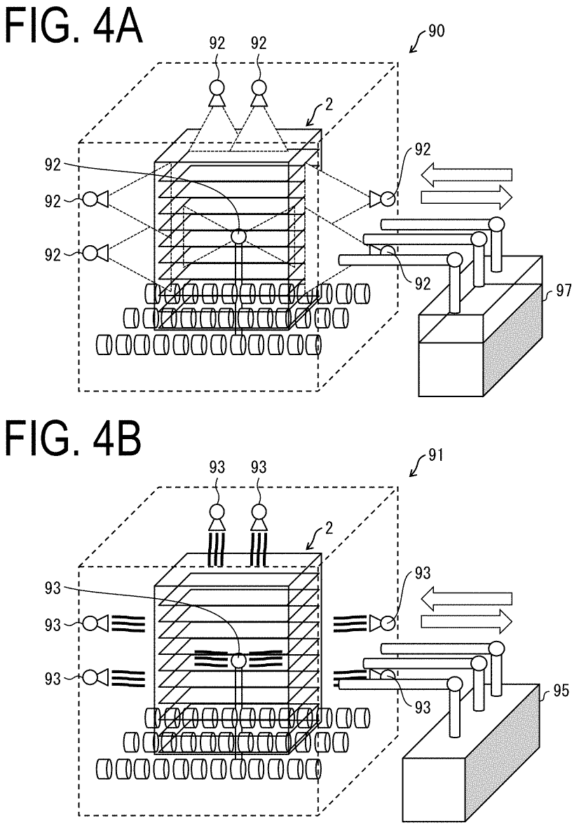

FIG. 4A is a schematic perspective view illustrating a substrate cleaning apparatus 90 according to a comparative example, and FIG. 4B is a schematic perspective view illustrating a cassette drying apparatus 91 according to the comparative example. The substrate cleaning apparatus 90 includes a plurality of cleaning nozzles 92, and a pure water tank 97 of a circulation system. The cleaning nozzle 92 pressures and injects pure water, supplied from the pure water tank 97, which is warmed by a heater or the like. This improves the capability of removing particles adhering to the mother glass substrate. The cleaning nozzle 92 is disposed not only at a position of the injection from the outside of the cassette 2, but also at a position of the injection from the inside of the cassette 2. This prevents the particles adhering to the mother glass substrate from remaining.

To prevent a non-cleaned region from being formed in the mother glass substrate during cleaning treatment, the cassette 2 is rotated or swung such that the mother glass substrate is uniformly cleaned.

The cassette drying apparatus 91 includes a plurality of blowing nozzles 93 and a warm air blower 95. To reduce time until the mother glass substrate that has been cleaned is dried, the blowing nozzles 93 (draining tools) are provided in the cassette drying apparatus 91. The blowing nozzles 93 are each disposed not only at a position of the injection from the outside of the cassette 2, but also at a position of the injection from the inside of the cassette 2. This prevents incomplete drying of the mother glass substrate mounted on the cassette 2.

To prevent a region without an air blow treatment from being formed in the mother glass substrate during drying treatment, the cassette 2 is rotated or swung such that the mother glass substrate is uniformly dried.

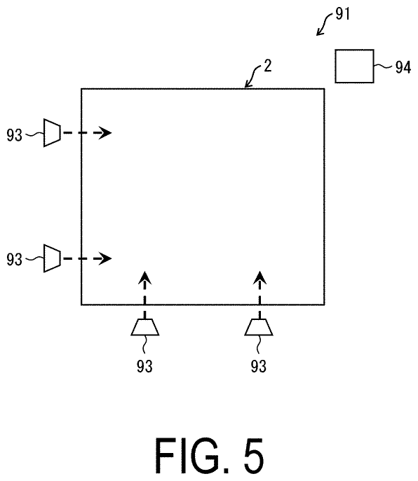

FIG. 5 is a plan view of the cassette drying apparatus 91 according to the comparative example. The plurality of blowing nozzles 93 are each disposed to inject hot air in a direction orthogonal to the corresponding side face of the cassette 2. The hot air injected from the blowing nozzles 93 is exhausted from an exhaust duct 94.

In a case that the plurality of blowing nozzles 93 are each disposed in the direction orthogonal to the corresponding side face of the cassette 2 as described above, a fine adjustment of the blowing nozzles 93 is required that allow hot air to be uniformly applied to the mother glass substrates to prevent incomplete drying of the mother glass substrates from occurring. Such an adjustment operation is complicated.

In contrast, the first embodiment only requires each of the plurality of blowing nozzles 3a to 3d to be disposed so as to inject the corresponding one of the hot air 13a to the hot air 13d along the plurality of side face portions 12a to 12d of the substrate cassette 2, respectively, so that a complicated adjustment of the blowing nozzles is unnecessary.

### Second Embodiment

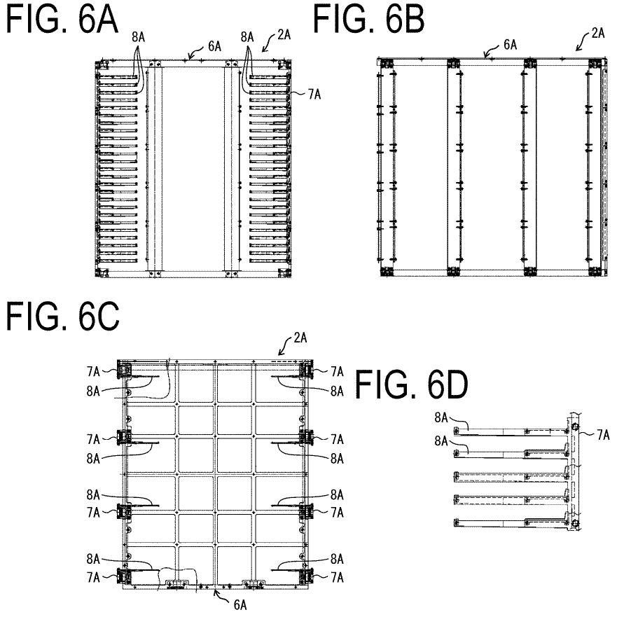

FIG. 6A is a front view of a cassette 2A provided in a cassette drying apparatus 1A according to a second embodiment, FIG. 6B is a plan view of the cassette 2A, FIG. 6C is a side view thereof, and FIG. 6D is a detailed view of a side plate 8A provided in the cassette 2A.

The substrate cassette 2A has a frame body 6A formed by assembling columnar members in a rectangular parallelepiped shape. On the right and left of the frame body 6A, a plurality of pairs of side plate fixing members 7A extending vertically are provided back and forth, and side by side. Each of the pairs of right and left side plate fixing members 7A is fixed to side plates 8A provided up and down at a predetermined interval. On the side plate 8A disposed back and forth at the same height, a mother glass substrate for forming an EL device is inserted.

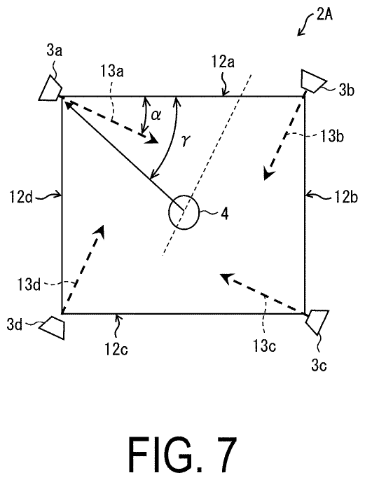

FIG. 7 is a plan view of a bottom face illustrating a placement direction of each of the first to fourth blowing nozzles 3a to 3d provided in the cassette drying apparatus according to the second embodiment. The same components as the components described above are designated by the same respective reference numerals. Then, detailed description of the components is not repeated.

The exhaust duct 4 is disposed in a central portion of a bottom face of the cassette 2A. The first to fourth blowing nozzles 3a to 3d are disposed on the corresponding extension lines of line segments connecting the exhaust duct 4 to respective vertexes of the cassette 2A.

Unlike the example illustrated in FIG. 3, the first blowing nozzle 3a injects hot air 13a toward the inside of the cassette 2A. An angle α between the hot air 13a injected from the first blowing nozzle 3a and the first side face portion 12a of the cassette 2A is equal to or less than an angle γ between a line segment connecting the exhaust duct 4 to the corresponding one of vertexes of the cassette 2A and the first side face portion 12a of the cassette 2A. A placement direction of each of the second to fourth blowing nozzles 3b to 3d is also similar to the placement direction of the first blowing nozzle 3a.

As described above, the first to fourth blowing nozzles 3a to 3d are each disposed in a direction to inject the corresponding one of the hot air 13a to the hot air 13d in a clockwise direction around the exhaust duct 4. Conversely, the first to fourth blowing nozzle 3a to 3d may be each disposed in a direction to inject the corresponding one of the hot air 13a to the hot air 13d in a counterclockwise direction around the exhaust duct 4.

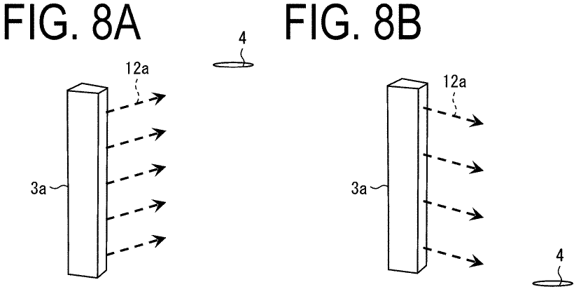

FIG. 8A illustrates an example of an injection direction of hot air 12a from the first blowing nozzle 3a, and FIG. 8B illustrates another example of an injection direction of the hot air 12a from the first blowing nozzle 3a. The first blowing nozzle 3a injects the hot air 12a along a horizontal direction. However, when the exhaust duct 4 is positioned above the first blowing nozzle 3a disposed on a top face of the cassette 2A, it is preferable that the first blowing nozzle 3a injects the hot air 12a obliquely upward as illustrated in FIG. 8A. When the exhaust duct 4 is positioned below the first blowing nozzle 3a disposed on a bottom face of the cassette 2A, it is preferable that the first blowing nozzle 3a injects the hot air 12a obliquely below as illustrated in FIG. 8B. The same applies to the second to fourth flow nozzles 3b to 3d. In addition, the same applies to the first embodiment.

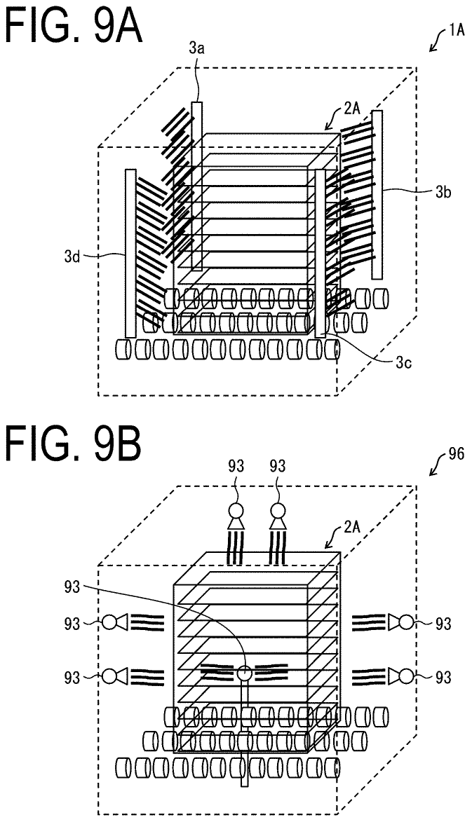

FIG. 9A is a schematic perspective view illustrating the cassette drying apparatus 1A according to the second embodiment, and FIG. 9B is a schematic perspective view illustrating a cassette drying apparatus 96 according to a comparative example.

The cassette drying apparatus 96 includes a plurality of blowing nozzles 93 as illustrated in FIG. 9B. To reduce time until the mother glass substrate that has been cleaned is dried, the blowing nozzles 93 (draining tools) are provided in the cassette drying apparatus 96. The blowing nozzles 93 are each disposed at not only a position for injection from outside the cassette 2A, but also a position for injection from the inside of the cassette 2A. This prevents incomplete drying of the mother glass substrate placed in the cassette 2A.

In a case that the plurality of blowing nozzles 93 are each disposed in the direction orthogonal to the corresponding side face of the cassette 2A as described above, a fine adjustment of the blowing nozzles 93 is required that allow hot air to be uniformly applied to the mother glass substrates to prevent incomplete drying of the mother glass substrates from occurring. Such an adjustment operation is complicated.

In contrast, according to the second embodiment, the blowing nozzles 3a to 3d are disposed to respectively inject the hot air 13a to 13d along the respective side face portions 12a to 12d of the substrate cassette 2A so that a complicated adjustment of the blowing nozzles is unnecessary.

### Third Embodiment

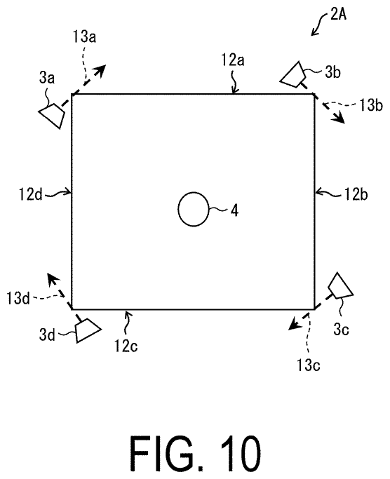

FIG. 10 is a plan view of a bottom face illustrating a placement direction of each of the first to fourth blowing nozzles 3a to 3d provided in a cassette drying apparatus according to a third embodiment. The same components as the components described above are designated by the same respective reference numerals. Then, detailed description of the components is not repeated.

As illustrated in FIG. 10, the first blowing nozzle 3a injects hot air 13a toward a first side face portion 12a from a position in a fourth side face portion 12d on a side of the first side face portion 12a. Then, the second blowing nozzle 3b injects hot air 13b toward a second side face portion 12b from a position in the first side face portion 12a on a side of the second side face portion 12b. The third blowing nozzle 3c injects hot air 13c toward a third side face portion 12c from a position in the second side face portion 12b on a side of the third side face portion 12c. The fourth blowing nozzle 3d injects hot air 13d toward a fourth side face portion 12d from a position in the third side face portion 12c on a side of the fourth side face portion 12d.

At a position corresponding to a central portion of a bottom face of the substrate cassette 2A, the exhaust duct 4 for exhausting the hot air 13a to 13d respectively injected from the first to fourth blowing nozzles 3a to 3d is disposed.

The hot air 13a injected from the first blowing nozzle 3a, the hot air 13b injected from the second blowing nozzle 3b, the hot air 13c injected from the third blowing nozzle 3c, and the hot air 13d injected from the fourth blowing nozzle 3d, are injected in respective directions away from the exhaust duct 4, enter the substrate cassette 2, and then are exhausted from the exhaust duct 4 while swirling in the substrate cassette 2.

As described above, the first to fourth blowing nozzles 3a to 3d are each disposed in a different direction to respectively inject the hot air 13a to 13d in a clockwise direction around the exhaust duct 4. Conversely, the first to fourth blowing nozzle 3a to 3d may be each disposed in a different direction to respectively inject the hot air 13a to 13d in a counterclockwise direction around the exhaust duct 4.

### Supplement

A cassette drying apparatus according to a first aspect of the disclosure includes a cassette formed by assembling columnar members in a polygonal pillar shape, the cassette being configured to accommodate a substrate, a plurality of blowing nozzles configured to inject air for drying the cassette, and an exhaust duct disposed at a position corresponding to a central portion of a top face or a bottom face of the cassette. Each of the plurality of blowing nozzles is disposed in a direction to inject the air in a clockwise direction around the exhaust duct, or each of the plurality of blowing nozzles is disposed in a direction to inject the air in a counterclockwise direction around the exhaust duct.

In a second aspect, the air injected from each of the plurality of blowing nozzles is exhausted from the exhaust duct while swirling in the cassette.

In a third aspect, the cassette is assembled in a quadrangular pillar shape.

In a fourth aspect, a plurality of side faces of the cassette include a first side face, a second side face adjacent to the first side face, a third side face disposed opposite to the first side face with respect to the second side face, and a fourth side face disposed opposite to the second side face with respect to the third side face, and the plurality of blowing nozzles include a first blowing nozzle configured to inject the air toward the second side face from the first side face on a side of the fourth side face, a second blowing nozzle configured to inject the air toward the third side face from the second side face on a side of the first side face, a third blowing nozzle configured to inject the air toward the fourth side face from the third side face on a side of the second side face, and a fourth blowing nozzle configured to inject the air toward the first side face from the fourth side face on a side of the third side face.

In a fifth aspect, one of the plurality of blowing nozzles is disposed on an extension line of a line segment connecting the exhaust duct to a vertex of the cassette.

In a sixth aspect, one of the plurality of blowing nozzles injects the air toward an outside of the cassette.

In a seventh aspect, an angle α between a direction of the air injected toward the outside of the cassette and a side face of the cassette is equal to or less than an angle β between a tangential line of a circle and the side face of the cassette, the circle being centered on the exhaust duct and passing through the plurality of blowing nozzles.

In an eighth aspect, one of the plurality of blowing nozzles injects the air toward an inside of the cassette.

In a ninth aspect, an angle α between a direction of the air injected toward the inside of the cassette and a side face of the cassette is equal to or less than an angle γ between a line segment connecting the exhaust duct to a vertex of the cassette and the side face of the cassette.

In a tenth aspect, the exhaust duct is disposed on a top face of the cassette, and the plurality of blowing nozzles inject the air obliquely upward; or the exhaust duct is disposed on a bottom face of the cassette, and the plurality of blowing nozzles inject the air obliquely downward.

In an eleventh aspect, the air injected from the plurality of blowing nozzles dries a substrate accommodated in the cassette.

In a twelfth aspect, the substrate is a mother glass substrate for forming an EL device, and the EL device includes an organic light emitting diode, an inorganic light emitting diode, or a quantum dot light emitting diode.

A cassette drying method of a thirteenth aspect includes an accommodating step for accommodating a substrate in a cassette formed by assembling columnar members in a polygonal pillar shape, a blowing step for injecting air for drying the cassette by using a plurality of blowing nozzles, and an exhausting step for exhausting the air from an exhaust duct disposed at a position corresponding to a central portion of a top face or a bottom face of the cassette. The plurality of blowing nozzles are each disposed in a direction to inject the air in a clockwise direction around the exhaust duct, or the plurality of blowing nozzles are each disposed in a direction to inject the air in a counterclockwise direction around the exhaust duct.

A manufacturing apparatus for an EL device of a fourteenth aspect includes a cassette formed by assembling columnar members in a polygonal pillar shape, the cassette being configured to accommodate a mother glass substrate for forming an EL device, a plurality of blowing nozzles configured to inject air for drying the cassette, and an exhaust duct disposed at a position corresponding to a central portion of a top face or a bottom face of the cassette. The plurality of blowing nozzles are each disposed in a direction to inject the air in a clockwise direction around the exhaust duct, or the plurality of blowing nozzles are each disposed in a direction to inject the air in a counterclockwise direction around the exhaust duct. The EL device includes an organic light emitting diode, an inorganic light emitting diode, or a quantum dot light emitting diode.

A manufacturing method for an EL device of a fifteenth aspect includes an accommodating step for accommodating a mother glass substrate for forming an EL device in a cassette formed by assembling columnar members in a polygonal pillar shape, a blowing step for injecting air for drying the cassette by using a plurality of blowing nozzles, and an exhausting step for exhausting the air from an exhaust duct disposed at a position corresponding to a central portion of a top face or a bottom face of the cassette. The plurality of blowing nozzles are each disposed in a direction to inject the air in a clockwise direction around the exhaust duct, or the plurality of blowing nozzles are each disposed in a direction to inject the air in a counterclockwise direction around the exhaust duct. The EL device includes an organic light emitting diode, an inorganic light emitting diode, or a quantum dot light emitting diode.

The disclosure is not limited to each of the embodiments described above, and various modifications may be implemented within a range not departing from the scope of the claims. Embodiments obtained by appropriately combining technical approaches described in each of the different embodiments also fall within the technical scope of the disclosure. Moreover, novel technical features may be formed by combining the technical approaches described in each of the embodiments.

### REFERENCE SIGNS LIST

1 Cassette drying apparatus
2 Cassette (substrate cassette)
3a First blowing nozzle (blowing nozzle)
3b Second blowing nozzle (blowing nozzle)
3c Third blowing nozzle (blowing nozzle)
3d Fourth blowing nozzle (blowing nozzle)
4 Exhaust duct
5 Columnar member
12a First side face portion (side face, first side face)
12b Second side face portion (side face, second side face)
12c Third side face portion (side face, third side face)
12d Fourth side face portion (side face, fourth side face)
13a to 13d Hot air (air)

1: A cassette drying apparatus comprising:
a cassette formed by assembling columnar members in a polygonal pillar shape, the cassette being configured to accommodate a substrate;
a plurality of blowing nozzles configured to inject air for drying the cassette; and
an exhaust duct disposed at a position corresponding to a central portion of a top face or a bottom face of the cassette,
wherein the plurality of blowing nozzles are disposed in a direction to inject the air in a clockwise direction around the exhaust duct, or the plurality of blowing nozzles are disposed in a direction to inject the air in a counterclockwise direction around the exhaust duct.

2: The cassette drying apparatus according to claim 1,
wherein the air injected from each of the plurality of blowing nozzles is exhausted from the exhaust duct while swirling in the cassette.

3: The cassette drying apparatus according to claim 1,
wherein the cassette is assembled in a quadrangular pillar shape.

4: The cassette drying apparatus according to claim 3,
wherein a plurality of side faces of the cassette includes a first side face, a second side face adjacent to the first side face, a third side face disposed opposite to the first side face with respect to the second side face, and a fourth side face disposed opposite to the second side face with respect to the third side face, and
the plurality of blowing nozzles include a first blowing nozzle configured to inject the air toward the second side face from the first side face on a side of the fourth side face, a second blowing nozzle configured to inject the air toward the third side face from the second side face on a side of the first side face, a third blowing nozzle configured to inject the air toward the fourth side face from the third side face on a side of the second side face, and a fourth blowing nozzle configured to inject the air toward the first side face from the fourth side face on a side of the third side face.

5: The cassette drying apparatus according to claim 3,
wherein one of the plurality of blowing nozzles is disposed on an extension line of a line segment connecting the exhaust duct to a vertex of the cassette.

6: The cassette drying apparatus according to claim 3,
wherein one of the plurality of blowing nozzles injects the air toward an outside of the cassette.

7: The cassette drying apparatus according to claim 6,
wherein an angle α between a direction of the air injected toward the outside of the cassette and a side face of the cassette is equal to or less than an angle β between a tangential line of a circle and the side face of the cassette, the circle being centered on the exhaust duct and passing through each of the plurality of blowing nozzles.

8: The cassette drying apparatus according to claim 3,
wherein one of the plurality of blowing nozzles injects the air toward an inside of the cassette.

9: The cassette drying apparatus according to claim 8,
wherein an angle α between a direction of the air injected toward the inside of the cassette and a side face of the cassette is equal to or less than an angle γ between a line segment connecting the exhaust duct to a vertex of the cassette and the side face of the cassette.

10: The cassette drying apparatus according to claim 1,
wherein the exhaust duct is disposed on a top face of the cassette, and the plurality of blowing nozzles inject the air obliquely upward, or the exhaust duct is disposed on a bottom face of the cassette, and the plurality of blowing nozzles inject the air obliquely downward.

11: The cassette drying apparatus according to claim 1,
wherein the air injected from the plurality of blowing nozzles dries a substrate accommodated in the cassette.

12: The cassette drying apparatus according to claim 1,
wherein the substrate is a mother glass substrate for forming an EL device, and
the EL device includes an organic light emitting diode, an inorganic light emitting diode, or a quantum dot light emitting diode.

13: (canceled)

14: A manufacturing apparatus for an EL device comprising:
a cassette formed by assembling columnar members in a polygonal pillar shape, the cassette being configured to accommodate a mother glass substrate for forming an EL device;
a plurality of blowing nozzles configured to inject air for drying the cassette; and
an exhaust duct disposed at a position corresponding to a central portion of a top face or a bottom face of the cassette,
wherein the plurality of blowing nozzles are disposed in a direction to inject the air in a clockwise direction around the exhaust duct, or the plurality of blowing nozzles are disposed in a direction to inject the air in a counterclockwise direction around the exhaust duct, and
the EL device includes an organic light emitting diode, an inorganic light emitting diode, or a quantum dot light emitting diode.

15: A manufacturing method for an EL device comprising:
an accommodating step for accommodating a mother glass substrate for forming an EL device in a cassette formed by assembling columnar members in a polygonal pillar shape;
a blowing step for injecting air for drying the cassette by using a plurality of blowing nozzles; and
an exhausting step for exhausting the air from an exhaust duct disposed at a position corresponding to a central portion of a top face or a bottom face of the cassette,
wherein the plurality of blowing nozzles are disposed in a direction to inject the air in a clockwise direction around the exhaust duct, or the plurality of blowing nozzles are disposed in a direction to inject the air in a counterclockwise direction around the exhaust duct, and
the EL device includes an organic light emitting diode, an inorganic light emitting diode, or a quantum dot light emitting diode.
